(19) United States
(12) Patent Application Publication
(10) Pub. No.: US 2008/0173967 A1
(43) Pub. Date: Jul. 24, 2008

(54) Image sensor and method for manufacturing the same

(75) Inventor: Woo Seok Hyun, Incheon (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/004,662

(22) Filed: Dec. 20, 2007

(30) Foreign Application Priority Data
Dec. 28, 2006 (KR) 10-2006-0136397

(51) Int. Cl. H01L 21/768; H01L 31/02

(52) U.S. Cl. 257/459; 438/653; 257/E31.114; 257/E21.584

(57) ABSTRACT

Disclosed is an image sensor, which includes a dielectric layer on a substrate having a photodiode, a metal interconnection layer on the dielectric layer and an upper insulating layer on the metal interconnection layer. The metal interconnection layer includes a lower barrier layer, a bulk metal layer on the lower barrier layer and an upper barrier layer on the bulk metal layer having a predetermined thickness which is 0.8 to 1.5 times as thick as the lower barrier layer.

The present application claims priority under 35 U.S.C. 119 and 35 U.S.C. 365 to Korean Patent Application No. 10-2006-0136397 (filed on Dec. 28, 2006), which is hereby incorporated by reference in its entirety.

### BACKGROUND

Embodiments of the invention relate to an image sensor and a method of manufacturing the same.

In general, an image sensor is a semiconductor device which converts an optical image into electrical signals, and is mainly divided into Charge Coupled Devices (CCD) and CIS (CMOS [Complementary Metal Oxide Silicon] Image Sensor) devices. The CMOS image sensor includes a photodiode and one or more MOS transistors that are formed in a unit pixel, and sequentially detects the electrical signals in a switching manner so as to realize an image.

The related CIS device is divided into a photodiode area which receives light signals to convert the light signals into the electrical signals, and a transistor area which processes the electrical signals. However, according to the related art, a metal interconnection formed on a substrate having a photodiode has a structure including a barrier metal at one side or both sides of the metal interconnection.

However, according to the related art as shown in FIG. 1, when a sintering process is performed after forming the metal interconnection and an upper insulating layer, the metal interconnection may be broken, thereby causing a metal void (V) or a circle defect (S). In addition, according to the related art, the circle defect (S) may occur during the sintering process, which is performed after forming the metal interconnection and the upper insulating layer.

The circle defect (S) or the metal void (V) may occur because a plug makes direct contact with an interlayer dielectric. That is, adhesion between the plug and the interlayer dielectric is weak, so that the interlayer dielectric is broken by heat applied thereto during the sintering process.

In addition, another reason of the circle defect (S) or the metal void (V) is the difference in stresses among the interlayer dielectric, the metal interconnection and the plug. In particular, according to the related art, a thickness of a barrier metal formed on a lower side or an upper side of the metal interconnection is not optimized, so that a circle defect (S) or metal void (V) may occur.

### SUMMARY

The embodiment provides an image sensor and a method of manufacturing the same, capable of preventing a metal void (V) or a circle defect (S) during a sintering process (after forming a metal interconnection or shield layer and an upper insulating layer).

An image sensor according to embodiments of the invention comprises a dielectric layer on a substrate having a photodiode (or photodiode array), a metal interconnection or shield layer on the dielectric layer, and an upper insulating layer on the metal interconnection or shield layer, wherein the metal interconnection or shield layer includes a lower barrier layer, a bulk metal layer on the lower barrier layer, and an upper barrier layer which is formed on the bulk metal layer in a predetermined thickness which is thicker than a thickness of the lower barrier layer by 0.8 to 1.5 times.

A method of manufacturing the image sensor according to the embodiment(s) comprises the steps of forming a dielectric layer on a substrate having a photodiode (or photodiode array), forming a lower barrier layer on the dielectric layer, forming a metal interconnection or shield layer on the lower barrier layer, forming an upper barrier layer on the metal interconnection or shield layer in a predetermined thickness, which is thicker than a thickness of the lower barrier layer by 0.8 to 1.5 times, forming an upper insulating layer on the upper barrier layer and sintering the substrate having the upper insulating layer.

A method of manufacturing an image sensor according to other embodiment(s) comprises the steps of forming a dielectric layer on a substrate having a photodiode (or photodiode array), forming a metal interconnection layer or shield layer on the dielectric layer, forming an upper insulating layer on the metal interconnection layer or shield layer, forming a sacrificial layer on the upper insulating layer, sintering the substrate having the sacrificial layer and removing the sacrificial layer from the substrate that has been sintered.

### BRIEF DESCRIPTION OF THE DRAWINGS

FIG. 1 is a photographic view representing a problem of an image sensor according to the related art;

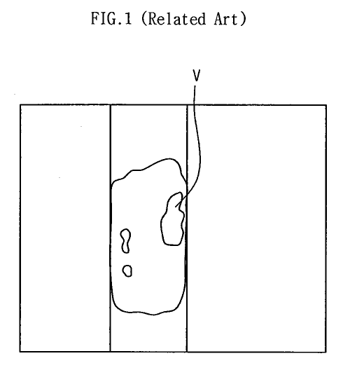

FIG. 2 is a cross-sectional view representing an exemplary metal interconnection layer or shield layer for an image sensor according to a first embodiment;

FIG. 3A is a photographic view representing an effect of the image sensor according to the first embodiment;

FIG. 3b is a layout view representing an exemplary CIS chip incorporating the exemplary metal interconnection layer or shield layer according to various embodiments;

FIGS. 4 to 5 are cross-sectional views representing a process of manufacturing an exemplary metal interconnection layer or shield layer for an image sensor according to other embodiments; and

FIG. 6 is a photographic view representing an effect of the image sensor according to the embodiment(s) of FIGS. 4-5.

### DETAILED DESCRIPTION OF THE EMBODIMENTS

Hereinafter, an image sensor and a method of manufacturing the same will be explained with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

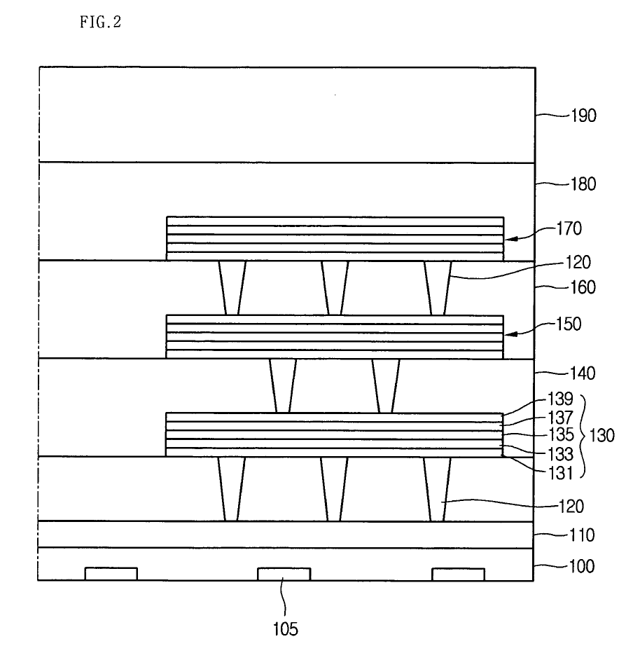

FIG. 2 is a cross-sectional view of an exemplary metal interconnection layer or shield layer for an image sensor according to various embodiments.

The exemplary metal interconnection layer or shield layer for an image sensor includes an interlayer (or premetal) dielectric 110 formed on a substrate 100 having a plurality of photodiodes 105, a metal interconnection layer 130 formed on the interlayer dielectric 110 and an upper insulating layer 190 formed on or over the metal interconnection layer 130. The metal interconnection layer 130 includes lower barrier and/or adhesion layers 131 and 133, a bulk metal layer 135 and upper barrier and/or adhesion layers 137 and 139, which are formed on the bulk metal layer 135 in a predetermined thickness which is thicker than a thickness of the lower barrier and/or adhesion layers 131 and 133 by 0.8 to 1.5 times.

According to the related art, the thickness of the barrier metal formed below (e.g., on a lower side) or above (e.g., an upper side of) the bulk metal layer is not optimized, so that differences in stress may occur among the dielectric layer, the bulk metal layer and a plug (e.g., 120), thereby causing a circle defect(S) or a metal void (V).

Thus, according to the exemplary embodiment(s), the circle defect (S) or the metal void (V) may be prevented by improving a metal structure of the metal interconnection layer or shield layer 130.

According to the exemplary embodiment(s), the metal structure of the metal interconnection layer or shield layer 130 includes the lower barrier and/or adhesion layers 131 and 133, the bulk metal layer 135 on the lower barrier and/or adhesion layers 131 and 133, and the upper barrier and/or adhesion layers 137 and 139 on the bulk metal layer 135 in a predetermined thickness which is thicker than a thickness of the lower barrier and/or adhesion layers 131 and 133 by 0.8 to 1.5 times. That is, the lower barrier and/or adhesion layers 131 and 133 include the first lower barrier and/or adhesion layer 131 which is formed on the dielectric layer 110 in a thickness of about 300 Å to 400 Å and the second barrier layer 133 which is formed on the first lower barrier layer 131 in a thickness of about 200 Å to 250 Å.

For example, a first lower barrier and/or adhesion layer 131 including Ti may be formed on the dielectric layer 110 in a thickness of about 350 Å, and a second lower barrier layer 133 including TiN may be formed on the first lower barrier and/or adhesion layer 131 in a thickness of about 220 Å. In addition, the bulk metal layer 135 may be formed on the second lower barrier layer 133 in a thickness of about 2000 Å to 7000 Å. For example, the bulk metal layer 135 may include Al having a thickness of about 6000 Å.

In addition, the upper barrier and/or adhesion layers 137 and 139 may include a first upper barrier and/or adhesion layer 137 which is formed on the metal interconnection 135 in a thickness of about 30 Å to 60 Å and a second upper barrier layer 139 which is formed on the first upper barrier layer 137 in a thickness of about 300 Å to 500 Å. For example, the upper barrier and/or adhesion layers 137 and 139 may comprise or consist of a first upper barrier and/or adhesion layer 137 including Ti, which may be formed on the bulk metal layer 135 in a thickness of about 50 Å, and a second upper barrier layer 139 including TiN, which may be formed on the second upper barrier and/or adhesion layer 137 in a thickness of about 450 Å.

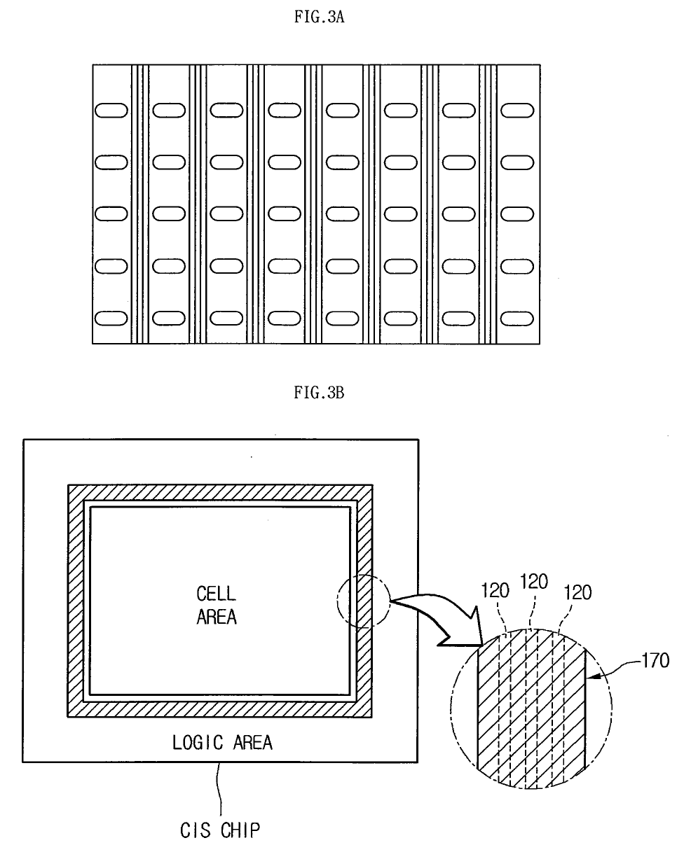

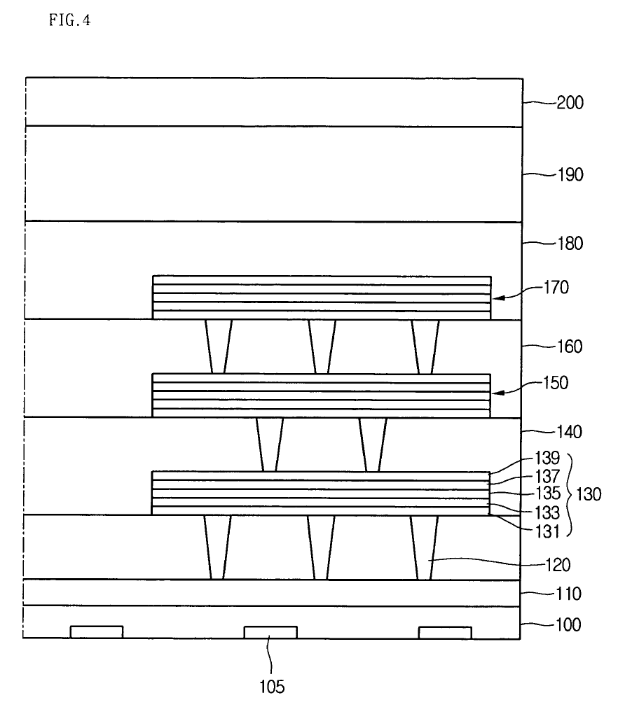

FIG. 3A is a photograph representing an effect of the embodiment(s) in an image sensor. As shown in FIG. 3A, different from the related art, according to the embodiments of the invention, a sintering process is performed after the metal structure is formed in the image sensor, so that the difference in stress among the dielectric layer 110, the bulk metal layer 135 and the plug 120 can be reduced, thereby preventing or reducing the incidence of metal voids (V) or circle defects (S).

As shown in FIG. 3B, the present metal structure comprising one or more metallization layers 170 (e.g., 3 or more metallization layers 130, 150 and 170, as shown in FIG. 2) may be formed in a ring around a cell or pixel area of a CIS chip, thereby forming a light-blocking shield and/or electromagnetic shield around the pixel array of the CIS chip.

Hereinafter, a method of manufacturing the image sensor according to the embodiment(s) will be described with reference to FIG. 2.

First, a first interlayer dielectric 110 is formed on the substrate 100 having the photodiodes 105. A plurality of plugs 120 are formed on in another dielectric layer on the first interlayer dielectric 110 or in a partial thickness of the first interlayer dielectric 110. Then, the first metal interconnection layer or shield layer 130 is formed on or over the interlayer dielectric layer 110.

In order to manufacture the first metal interconnection layer 130, the lower barrier and/or adhesion layers 131 and 133 are formed on the first dielectric layer 110. In this case, the first lower barrier and/or adhesion layer 131 is formed on the interlayer dielectric 110 in a thickness of about 300 Å to 400 Å, and the second lower barrier layer 133 is formed on the first lower barrier layer 131 in a thickness of about 200 Å to 250 Å. For example, the first lower barrier and/or adhesion layer 131 may include Ti and be formed on the first interlayer dielectric 110 in a thickness of about 350 Å, and the second lower barrier layer 133 may include TiN and be formed on the first lower barrier and/or adhesion layer 131 in a thickness of about 220 Å.

Then, a bulk metal layer 135 is formed on the lower barrier and/or adhesion layers 131 and 133. In this case, a bulk metal layer 135 having a thickness of about 2000 Å to 7000 Å may be formed on the second lower barrier layer 133. For example, the bulk metal layer 135 may include Al having a thickness of about 6000 Å.

After that, the upper barrier and/or adhesion layers 137 and 139 are formed on the bulk metal layer 135 in a predetermined thickness which is thicker than a thickness of the lower barrier and/or adhesion layers 131 and 133 by 0.8 to 1.5 times. In the present invention, either the combined thickness of the upper layers 137 and 139 is 0.8-1.5 times the thickness of the lower layers 131 and 133, or the thickness of the upper barrier layer 139 is 0.8-1.5 times the thickness of the lower barrier layer 133.

In addition, the upper barrier and/or adhesion layers 137 and 139 include the first upper barrier and/or adhesion layer 137 formed on the bulk metal layer 135 in a thickness of about 30 Å to 60 Å and the second upper barrier layer 139 formed on the first barrier and/or adhesion layer 137 in a thickness of about 300 Å to 500 Å. For example, the upper barrier and/or adhesion layers 137 and 139 comprise or consist of the first upper barrier and/or adhesion layer 137 which may include Ti and be formed on the bulk metal layer 135 in a thickness of about 50 Å, and the second upper barrier layer 139 may include TiN and be formed on the first upper barrier and/or adhesion layer 137 in a thickness of about 450 Å.

Then, a second interlayer dielectric 140 is formed on the substrate 100 having the first metal interconnection layer 130. After that, a second metal interconnection layer 150 is formed, and then a third interlayer dielectric 160 is formed. Then, a third metal interconnection layer 170 is formed on the third interlayer dielectric 160. After that, a fourth interlayer dielectric 180 is formed on the third metal interconnection layer 170.

After that, the upper insulating layer 190 is formed on the substrate 100 having the fourth interlayer dielectric 180 thereon, and the sintering process is performed on the substrate 100. Then, processes of forming a color filter layer (not shown), a planarization layer (not shown) and a micro-lens (not shown) can be performed on the upper insulating layer 190 that has been sintered.

As shown in FIG. 5, different from the related art, according to the first embodiment, the sintering process is performed on a different metal structure, so that the difference in stress among the interlayer dielectric, the metal interconnection and the plug can be reduced, thereby preventing or reducing an incidence of metal voids (V) and/or circle defects (S).

Hereinafter, a method of manufacturing an image sensor according to other embodiment(s) will be described.

According to the other embodiment(s), the sintering process may be performed after forming a sacrificial layer, so that a thermal effect occurring in the sintering process is minimized and the upper insulating layer and the interlayer dielectric are supported or contained by the sacrificial layer, thereby preventing or reducing an incidence of metal voids (V) and/or circle defects (S).

An exemplary image sensor according to the alternative embodiment(s) can be manufactured by adopting the method of manufacturing the image sensor according to the embodiment(s) described above.

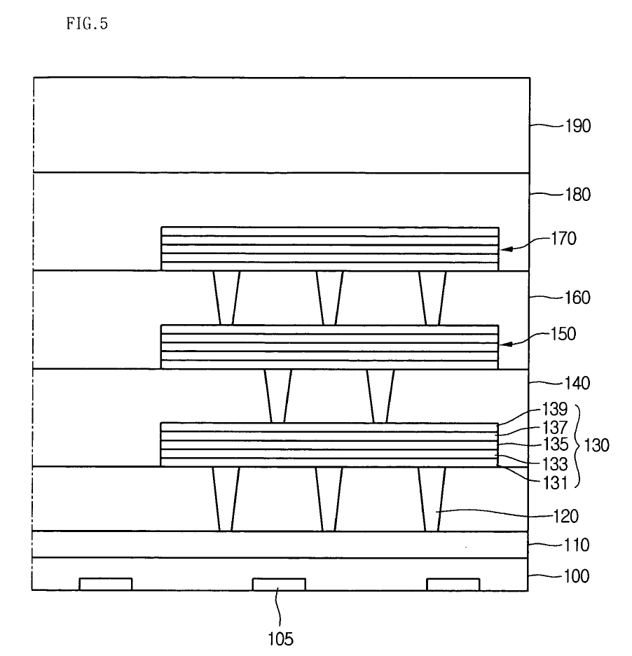

FIGS. 4 and 5 are sectional views representing an alternative process of manufacturing the image sensor. First, as shown in FIG. 4, the first interlayer dielectric 110 is formed on the substrate 100 having the plurality of photodiodes 105. Then, the first plurality of vias 120 are formed in the first interlayer dielectric 110, and the first metal interconnection layer 130 is formed on the first interlayer dielectric 110 including the first plurality of vias 120.

According to the alternative embodiment(s), the first metal interconnection layer 130 has a metal structure including lower barrier and/or adhesion layers 131 and 133, a bulk metal layer 135 on the lower barrier and/or adhesion layers 131 and 133, and upper barrier and/or adhesion layers 137 and 139 formed on the bulk metal layer 135 in a predetermined thickness which is thicker than a thickness of the lower barrier and/or adhesion layers 131 and 133 by 0.8 to 1.5 times, as described above. For example, the lower barrier and/or adhesion layers 131 and 133 include the first lower barrier and/or adhesion layer 131 on the first interlayer dielectric 110 in a thickness of about 300 Å to 400 Å, and the second lower barrier layer 133 on the first lower barrier and/or adhesion layer 131 in a thickness of about 200 Å to 250 Å. In addition, the bulk metal layer 135 is formed on the second lower barrier layer 133 in a thickness of about 2000 Å to 7000 Å.

Further, the upper barrier and/or adhesion layers 137 and 139 include the first upper barrier and/or adhesion layer 137 on the metal interconnection 135 in a thickness of about 30 Å to 60 Å, and the second upper barrier layer 139 on the first upper barrier layer 137 in a thickness of about 300 Å to 500 Å.

After that, the second interlayer dielectric 140 is formed on the substrate 100 having the first metal interconnection layer 130, and a second plurality of vias 120 are formed therein. Then, after forming the second metal interconnection layer 150, the third interlayer dielectric 160 is formed, and a third plurality of vias 120 are formed therein. After that, the third metal interconnection 170 is formed on the third interlayer dielectric 160, and a fourth interlayer dielectric 180 is formed on the third metal interconnection layer 170.

Then, an upper insulating layer 190 is formed on the substrate 100 having the fourth interlayer dielectric 180. The upper insulating layer 190 includes SiN or other material having a stiffness or modulus of elasticity greater than that of dielectric layer 180. Then, a sacrificial layer 200 is formed on the upper insulating layer 190.

According to the alternative embodiment(s), the sintering process is performed after forming the sacrificial layer, so that the thermal effect occurring in the sintering process is minimized and the upper insulating layer 190 and the interlayer dielectric 180 are supported or contained by the sacrificial layer 200, thereby preventing or reducing an incidence of metal voids (V) and/or circle defects (S). To this end, the sacrificial layer 200 may include a metal layer having a thickness of about 1000 Å to 3000 Å. After that, the substrate 100 having the sacrificial layer 200 is sintered.

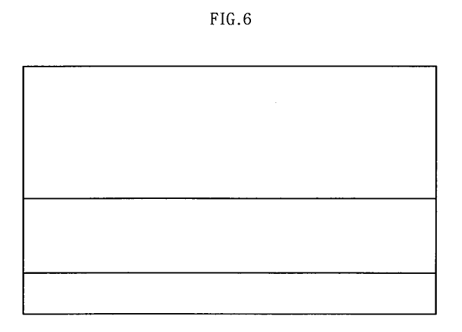

FIG. 6 is a photograph representing the effect of the metal interconnection layer or shield layer for an image sensor according to the alternative embodiment(s). As shown FIG. 6, different from the related art, in the structure of the metal interconnection layer or shield layer, the sacrificial layer is formed before the sintering process, so that the thermal effect occurring in the sintering process is minimized, and the insulating layer 190 and the interlayer dielectric 180 are supported or contained by the sacrificial layer 200, thereby preventing or reducing an incidence of metal voids (V) and/or circle defects (S).

After that, as shown in FIG. 5, the sacrificial layer 200 is removed from the substrate 100 that has been sintered. The sacrificial layer 200 can be removed by an etch back process, a wet etch process, or a CMP (Chemical Mechanical Polishing) process.

Then, processes of making or manufacturing a color filter layer (not shown), a planarization layer (not shown) and a microlens array (not shown) can be performed on the upper insulating layer 190 that has been sintered.

In the image sensor and the method of manufacturing the image sensor according to the embodiments, the sintering process is performed after the metal structure (e.g., shielding layer[s]) of the image sensor is formed, so that the difference in stress among the interlayer dielectric(s), the metal interconnection or shield layer(s) and the plug(s) can be reduced, thereby preventing or reducing an incidence of metal voids (V) and/or circle defects (S).

In addition, different from the related art, in the structure of the metal interconnection layer or shield layer in the image sensor according to embodiments of the invention, a sacrificial layer may be formed before the sintering process, so that the thermal effect(s) that may occur in the sintering process can be minimized, and the upper insulating layer(s) and the interlayer dielectric(s) can be contained or supported by the sacrificial layer, thereby preventing or reducing an incidence of metal void(s) (V) and circle defect(s) (S).

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a dielectric layer on a substrate having a photodiode;
a metal interconnection layer on the dielectric layer; and
an upper insulating layer on the metal interconnection layer,
wherein the metal interconnection layer includes a lower barrier layer, a bulk metal layer on the lower barrier layer, and an upper barrier layer on the bulk metal layer in a predetermined thickness which is 0.8 to 1.5 times a thickness of the lower barrier layer.

2. The image sensor as claimed in claim 1, wherein the lower barrier layer includes a first lower barrier and/or adhesion layer on the dielectric layer in a thickness of about 300 Å to 400 Å, and a second lower barrier layer on the first lower barrier and/or adhesion layer in a thickness of about 200 Å to 250 Å.

3. The image sensor as claimed in claim 2, wherein the first lower barrier and/or adhesion layer includes Ti, and the second lower barrier layer includes TiN.

4. The image sensor as claimed in claim 2, wherein the bulk metal layer is on the second lower barrier layer in a thickness of about 2000 Å to 7000 Å.

5. The image sensor as claimed in claim 4, wherein the bulk metal layer includes Al.

6. The image sensor as claimed as claim 2, wherein the upper barrier layer includes a first upper barrier and/or adhesion layer on the bulk metal layer in a thickness of about 30 Å to 60 Å, and a second upper barrier layer on the first upper barrier and/or adhesion layer in a thickness of about 300 Å to 500 Å.

7. The image sensor as claimed in claim 6, wherein the first upper barrier and/or adhesion layer includes Ti, and the second upper barrier layer includes TiN.

8. A method of manufacturing an image sensor, the method comprising the steps of:
forming a dielectric layer on a substrate having a photodiode;
forming a lower barrier layer on the interlayer dielectric;
forming a bulk metal layer on the lower barrier layer;
forming an upper barrier layer on the bulk metal layer in a predetermined thickness, which is 0.8 to 1.5 times a thickness of the lower barrier layer;
forming an upper insulating layer on the upper barrier layer; and
sintering the substrate having the upper insulating layer.

9. The method as claimed in claim 8, wherein the step of forming the lower barrier layer on the dielectric layer comprises the steps of:
forming a first lower barrier and/or adhesion layer on the interlayer dielectric in a thickness of 300 Å to 400 Å; and
forming a second lower barrier layer on the first lower barrier and/or adhesion layer in a thickness of about 200 Å to 250 Å.

10. The method as claimed in claim 9, wherein the first lower barrier and/or adhesion layer includes Ti, and the second lower barrier layer includes TiN.

11. The method as claimed in claim 9, wherein the bulk metal layer has a thickness of about 2000 Å to 7000 Å.

12. The method as claimed in claim 9, wherein the step of forming the upper barrier layer on the bulk metal layer comprises the steps of:
forming a first upper barrier and/or adhesion layer on the metal interconnection in a thickness of about 30 Å to 60 Å; and
forming a second upper barrier layer on the first upper barrier and/or adhesion layer in a thickness of about 300 Å to 500 Å.

13. A method of manufacturing an image sensor, the method comprising the steps of:
forming a dielectric layer on a substrate having a photodiode;
forming a metal interconnection layer on the dielectric layer;
forming an upper insulating layer on the metal interconnection layer;
forming a sacrificial layer on the upper insulating layer;
sintering the substrate having the sacrificial layer; and
removing the sacrificial layer from the substrate that has been sintered.

14. The method as claimed in claim 13, wherein the sacrificial layer includes a metal layer.

15. The method as claimed in claim 13, wherein the sacrificial layer has a thickness of about 1000 Å to 3000 Å.

16. The method as claimed in claim 13, wherein the sacrificial layer is removed by an etch back process.

17. The method as claimed in claim 13, wherein the sacrificial layer is removed by chemical mechanical polishing.

18. The method as claimed in claim 13, wherein the step of forming the metal interconnection layer comprises the steps of:
forming a lower barrier layer on the interlayer dielectric layer;
forming a bulk metal layer on the lower barrier layer; and
forming an upper barrier layer on the metal interconnection in a predetermined thickness that is 1 to 1.5 times, a thickness of the lower barrier layer.

19. The method as claimed in claim 13, wherein the step of forming the lower barrier layer on the dielectric layer comprises the steps of:
forming a first barrier and/or adhesion layer on the interlayer dielectric in a thickness of about 300 Å to 400 Å; and
forming a second barrier layer on the first lower barrier layer in a thickness of about 200 Å to 250 Å.

20. The method as claim in claim 19, wherein the step of forming the upper barrier layer on the metal interconnection comprises the steps of:
forming a first upper barrier and/or adhesion layer in a thickness of about 30 Å to 60 Å; and
forming a second barrier layer on the first barrier layer in a thickness of about 450 Å to 400 Å.
